(19) United States
(12) Patent Application Publication
(10) Pub. No.: US 2009/0121586 A1
(43) Pub. Date: May 14, 2009

(54) Apparatus for transforming inverse piezoelectric effect into rotary motion and method of manufacturing aforementioned apparatus

(75) Inventor: Boris Kesil, San Jose, CA (US)

Correspondence Address: Boris Kesil;MULTIMETRIXS, LLC., 1040 Di Giulio Avenue #200, Santa Clara, CA, 95050, US

(73) Assignee: MULTIMETRIXS, LLC.

(21) Appl. No.: 11/983,715

(22) Filed: Nov. 13, 2007

(51) Int. Cl. H02N 2/12; H01L 41/22

(52) U.S. Cl. 310/323.02; 29/25.35

(57) ABSTRACT

An electric motor operating on the principle of conversion of inverse piezoelectric oscillations into continuous rotation. The motor has a stator having a flange that on a bearing rotatingly supports a shaft with a cup-shaped stator attached to the shaft. The flange also supports a ring-shaped piezoelectric element, the outer surface of which is embraced with an elastic band having radial outward blades. The blades abut the inner surface of the rotor and are inclined at an angle that in the point of contact between the tips of the blades and the rotor provides development of a force component in the direction of the rotation of the rotor. The ring-shaped piezoelectric element is fitted onto a collet that compensates for contractions and expansions of the piezoelectric element under the inverse piezoelectric effect.

### FIELD OF THE INVENTION

The present invention relates to apparatuses for transforming linear motion into rotary motion, in particular to an apparatus of the aforementioned type having a stator assembly for frictional engagement with a ring of a rotor of a rotary motor, and, more specifically, to the aforementioned apparatus in the form of a stepper motor having a stator assembly and a rotor assembly, which is driven into rotation by a piezoelectric member through a plurality of pusher blades that extend radially outward from the piezoelectric member. The invention also relates to a method of manufacturing the aforementioned device, and, in particular, to the elastic band with pusher blades that transmit motion from the piezoelectric member to the rotor.

### BACKGROUND OF THE INVENTION

Piezoelectricity is the ability of some materials (notably crystals and certain ceramics) to generate an electric potential in response to applied mechanical stress. The piezoelectric effect is reversible in that materials exhibiting the direct piezoelectric effect (the production of electricity when stress is applied) also exhibit the converse piezoelectric effect (the production of stress and/or strain when an electric field is applied). Piezoelectricity finds useful applications in the production and detection of sound, generation of high voltages, electronic frequency generation, microbalances, ultrafine focusing of optical assemblies, as well as in mechanisms for conversion of piezoelectric oscillations into continuous rotary or linear movement.

Rotary motors using a piezoelectric effect are known in the art. For example, U.S. Pat. No. 7,116,037 issued in 2006 to Moteki, et al., discloses a rotary drive device configured to be reduced in size while still delivering a prescribed torque. The rotary drive device has a base part with a vibrating body and a rotating body attached to the base part. The vibrating body has at least one piezoelectric element that vibrates an abutting part, which rotates the rotating body. Specifically, the rotating body has a contact part that is positioned at a prescribed distance from the rotational center and that abuts against by the abutting part. When voltage is applied to the piezoelectric element, the vibrating body vibrates to repetitively press the abutting part against the contact part to rotate the rotating body. The vibrating body is positioned in a plane that intersects the rotational axis of the rotating body, and is disposed at least as close to the rotational axis of the rotating body as that of the contact part.

U.S. Pat. No. 7,095,160 issued in 2006 to K. Uchino, et al., discloses a rotary ultrasonic piezoelectric motor that includes a stator having a piezoelectric ceramic disc polarized in the radial direction and bounded by a top electrode and a segmented bottom electrode. The motor also includes a power source for applying two pairs of alternating voltages to the bottom electrode segments to excite a shear-shear mode vibration in the stator, resulting in a shear-shear mode flexure traveling wave in the stator. The motor further includes a rotor operatively connected to the stator, and the stator is driven to rotate through a frictional force between the rotor and the stator due to the traveling wave deformation of the stator. U.S. Pat. No. 6,242,849 issued in 2001 to S. Burov discloses a piezoelectric stepping motor that comprises a housing, a stator in the form of a cylindrical, hollow piezoelectric cylinder inside a cylindrical rotor frictionally interacting with the stator. The stator comprises at least two rotary-fixing and fixing piezoelectric units which are disposed inside the housing one behind the other in a longitudinal plane, the rotary-fixing piezoelectric unit comprising a rotary and fixing piezoelectric cells, insulators and a friction element, and the fixing piezoelectric unit comprising a fixing piezoelectric cell, insulators, and a friction element, or the stator comprises at least two pairs of piezoelectric units disposed at least in one transversal plane and shaped in the from of sectors. The housing may be movable, and piezoelectric units may be fixed on the motionless rotor.

Another known device described in U.S. Pat. No. 7,218,031 issued in 2007 to O. Vyshnevskyy, et al., relates to a piezoelectric motor having small plates or pusher blades secured to the outer surface of a ring such that the pusher blades extend radially therefrom. A second ring is exposed on the outside, the inner ring effectively becoming an axle. The pusher blades are plated such that pressure applied to the pusher blades results in an electric discharge.

Conversely, electrical charge applied to the pusher blades causes the pusher blades to oscillate. The pusher blades are secured to the inner ring at an angle so that as the inner ring pulses, the pusher blades bend against the outer ring, thereby rotating the outer ring. Accordingly, expansion of the inner ring resulting from the piezoelectric effect of the inner ring being coated results in compression of the pusher blades, and this also causes movement of the inner ring relative to the outer ring. In other words, movement is relative, depending on which ring is stationary. These configurations are problematic. Inward expansion is prevented since the ring expands outwardly, resulting in loss of efficiency in potential movement and work capacity.

Electricity pulsed at speeds at or exceeding 60,000 pulses per second results in considerable wear on the inside ring and eventually results in separation of the inner plating from the inside ring. Microscopic deformations occur on the ring which eventually cause ring breakage. Since all pusher blades do not function mechanically the same, each has a slightly different orientation. A different effect of ceramic plating on each pusher blade is characterized by uneven wear and loss of power.

### OBJECTS AND SUMMARY OF THE INVENTION

It is an object of the invention to provide a device that prevents buildup of microscopic deformations in the ring that eventually cause ring breakage.

It is another object to provide a device that is operable at high speeds while preventing significant wear on the inside ring that could otherwise result in separation of the inner plating from the inner ring.

It is a further object to provide a device that ensures that each pusher blade is uniformly secured to the ring with the same orientation, ensuring even and efficient transmission of energy through each pusher blade.

It is still another object to provide a simple and reliable method of manufacturing and assembling an apparatus for conversion of linear piezoelectric oscillations into a continuous rotary motion.

It is a further object to provide a method of manufacturing and assembly of a pusher-blade elastic band of the aforementioned apparatus that will eliminate imperfections and inconsistencies in the pusher blades of the elastic band, resulting in loss of energy caused by differences in functional angles, configurations, shapes, and sizes of the pusher blades.

The invention provides an apparatus for transforming inverse piezoelectric effect into rotary motion. The apparatus contains a stator assembly, a rotor assembly, and an elastic band with pusher blades between the rotor and stator assemblies. More specifically, the stator assembly of the apparatus enables cooperative engagement with a ring of a rotor of a rotary motor. The stator assembly includes a collet, a piezoelectric member, and the aforementioned elastic band. The inner hub-shaped collet has a flexible flange disposed in an axial direction. The piezoelectric element is also cylindrical, the inner surface of the piezoelectric element being in direct engagement with the collet and the outer surface of the piezoelectric element being in direct engagement with the elastic band. An elastic band is formed with pusher blades punched therefrom, the pusher blades all being integral therewith and all made at the same angle. The pusher blades are bent outwardly in the same direction and away from the band. A Teflon coating is then applied to the pusher blades to improve resistance to wear.

The elastic band includes a pair of torsion spirals disposed on each respective end thereof. The torsion spirals securely retain the elastic band about the piezoelectric element. The pair of torsion spirals disposed at one end of the band is curled upwardly, and the torsion spirals at the other end of the strip are both curled downwardly. The elongated strip is formed into a ring by locking the torsion spirals together. This construction strengthens each blade while eliminating the need for solder, brazing, or any similar operations to form the ring from the strip.

The device of the invention enables a ring of the rotor to be force-fit over the pusher blades in spring movement with the pusher blades. Thus, outward expansion of the ring causes the pusher blades to engage the ring, always biasing the ring in the direction tangential to the circumference of the ring of the rotor and thus turning the rotor.

### BRIEF DESCRIPTION OF THE DRAWINGS

Other advantages of the present invention will be readily appreciated as the invention is better understood with reference to the following detailed description when considered in connection with the accompanying drawings.

### BRIEF DESCRIPTION OF THE DRAWINGS

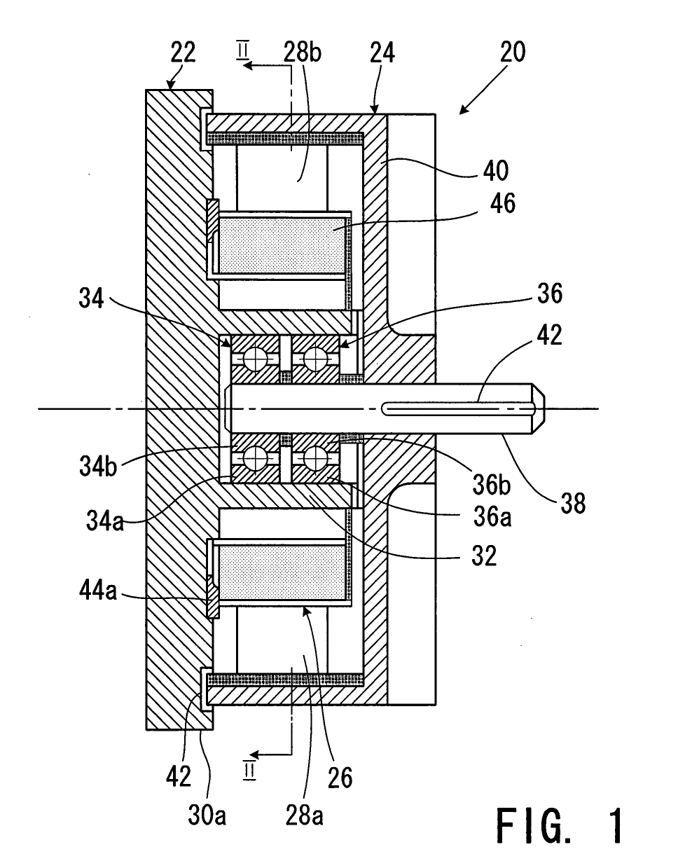

FIG. 1 is an axial sectional view of the motor of the present invention.

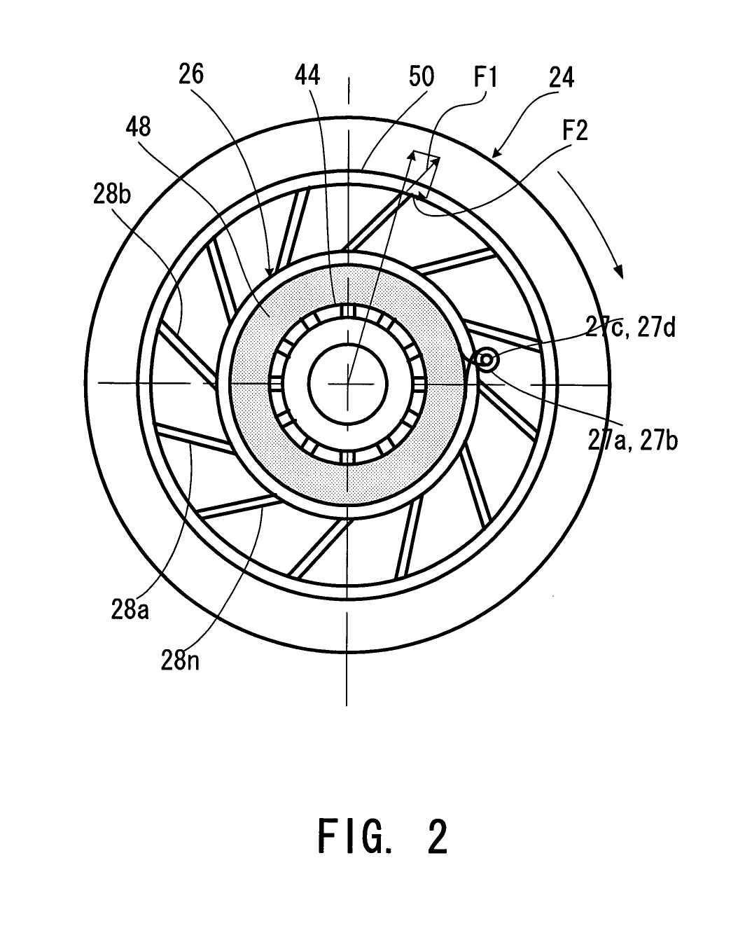

FIG. 2 is a cross-sectional view of the motor along line II-II of FIG. 1.

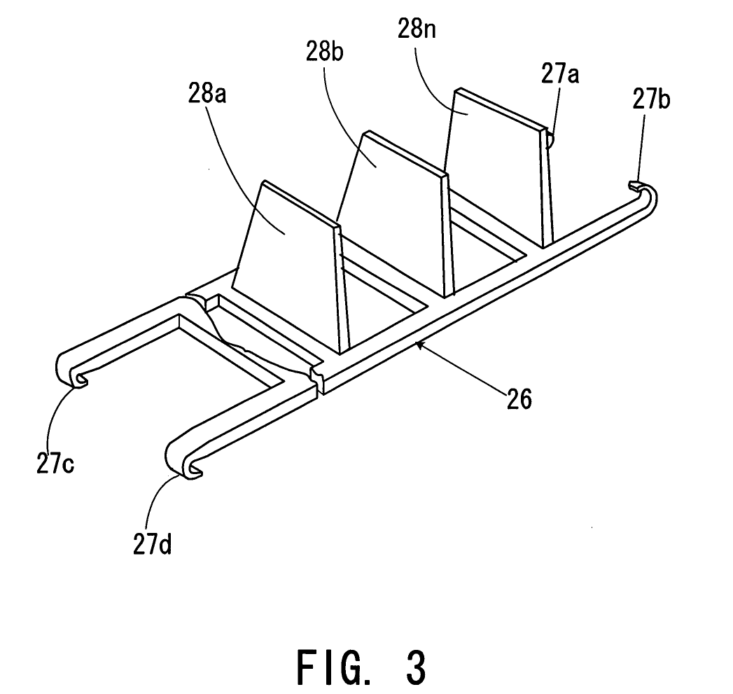

FIG. 3 is a three-dimensional view of the elastic band with pusher blades for interaction with the ring on the inner surface of the rotor used in the motor of FIG. 1.

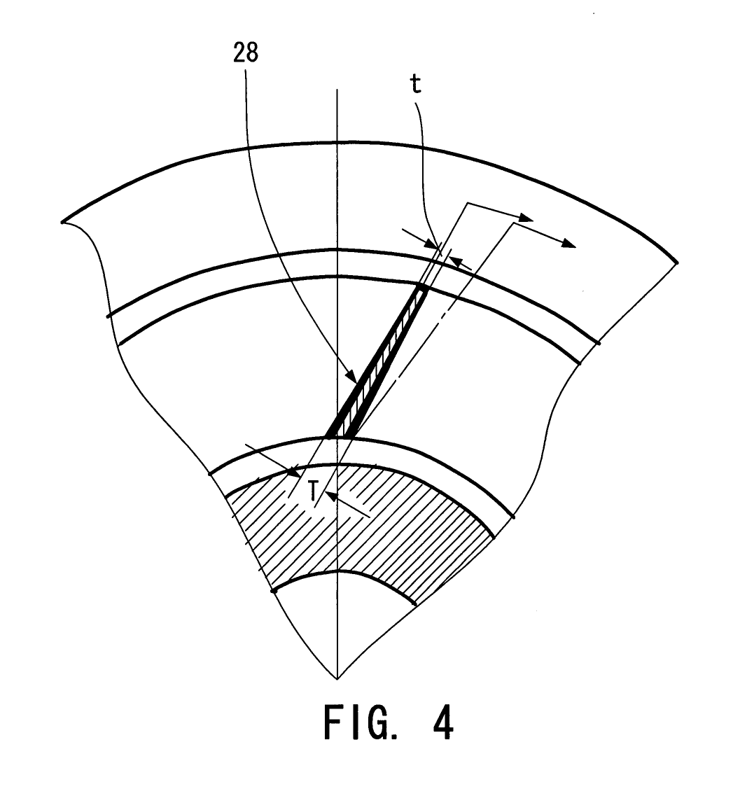

FIG. 4 is a fragmental view illustrating the shape of one of the blades with coating.

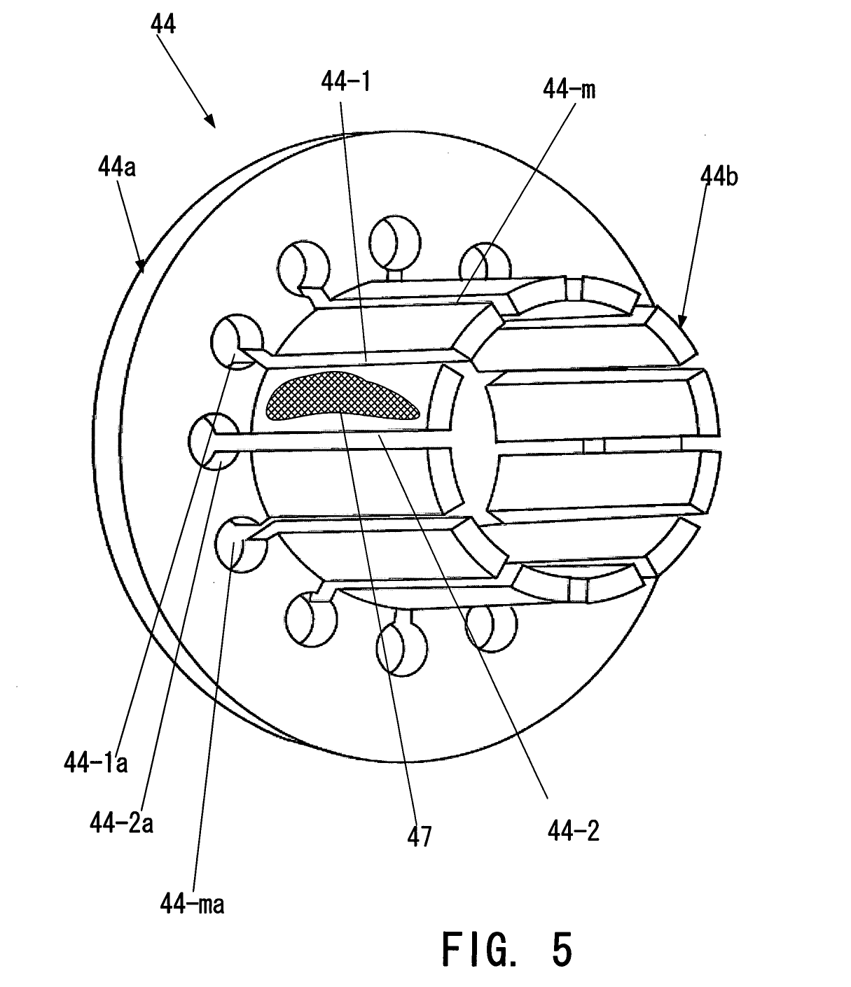

FIG. 5 is a three-dimensional view of a collet used to support the piezoelectric ring of the invention.

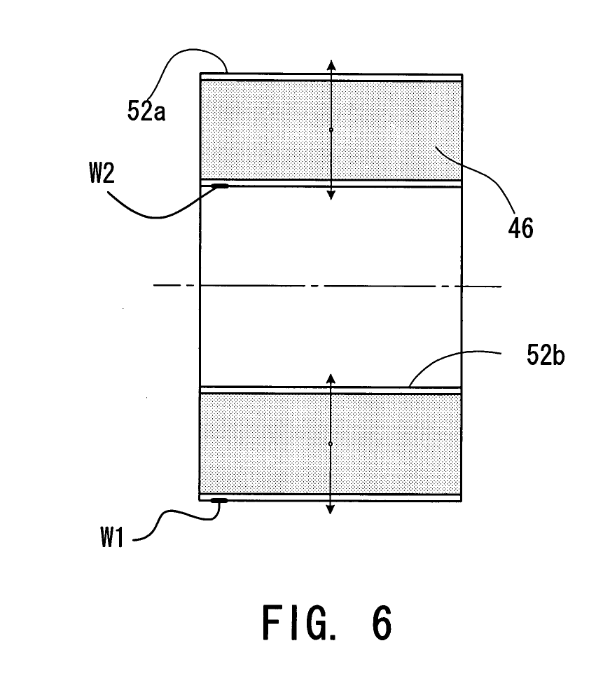

FIG. 6 is a piezoelectric ring of the invention shown in an axial sectional plane.

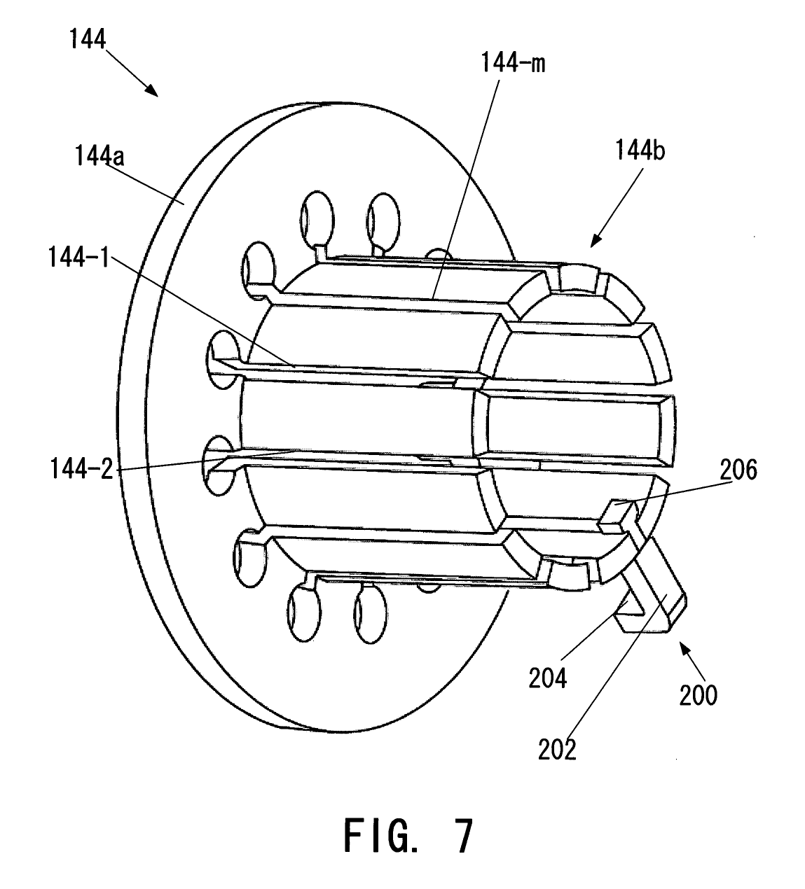

FIG. 7 is a three-dimensional view of a collet according to another modification of the invention.

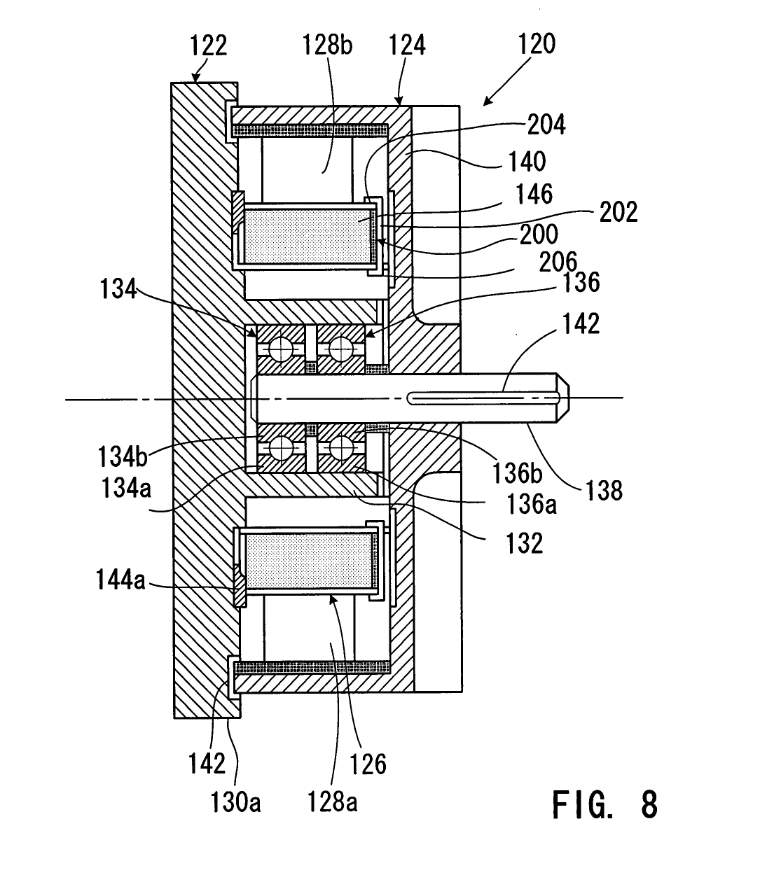

FIG. 8 is a sectional view similar to FIG. 1 but using the collet of FIG. 7.

### DETAILED DESCRIPTION OF THE PREFERRED EMBODIMENT

The apparatus of the invention will be illustrated in the form of a rotary motor. The rotary motor of the invention in which an inverse piezoelectric effect is transformed into a rotary motion is shown in FIGS. 1 and 2, where FIG. 1 is an axial sectional view of the motor and FIG. 2 is a cross-sectional view of the motor along line II-II of FIG. 1. It can be seen that the motor, which as a whole is designated by reference numeral 20, contains a stator assembly 22, a rotor assembly 24, and an elastic band 26 with a plurality of radial pusher blades 28a, 28b, . . . 28n (FIG. 2).

The stator assembly 22 consists of a flanged member 30 with a central hollow cylindrical hub 32 that houses a bearing assembly which consists of two radial ball bearings 34 and 36. The outer rings 34a and 34b of these bearings are press-fitted into the interior of the hub 32, while the inner rings 36a and 36b of the bearings 34 and 36 are press-fitted onto a rotary shaft 38 of the rotor assembly 24. The rotor assembly has a cup-shaped rotor 40 that is secured on the rotary shaft 38, e.g., by means of a key 42, in a position such that the open side of the cup-shaped rotor faces the flange member 30 and so that the mating end face of the cup-shaped rotor 40 enters an annular recess 42 on the side of the flange member that faces the cup-shaped rotor 40. The recess 42 and the mating end of the rotor 40 inserted into the recess form a kind of labyrinth seal that protects the interior of the motor from penetration of dust, dirt, or other contaminants.

The stator assembly 22 includes a springing member, e.g., a collet 44 (FIGS. 1 and 2) that supports a piezoelectric element in the form of a piezoelectric ring 46 with the aforementioned elastic band 26 secured on the periphery of the piezoelectric ring 46 and having the aforementioned pusher blades 28a, 28b, . . . 28n that enable cooperative engagement with a ring 50 which is secured to the inner circumferential surface of the cup-shaped rotor 40.

FIG. 3 is a three-dimensional view of the elastic band 26, which is in a straight form prior to winding onto the piezoelectric ring 46. It can be seen that the pusher blades can be punched out at a predetermined angle from the elastic band 26 so that in an assembled state of the stator assembly 22, the pusher blades protrude radially outward from the elastic band 26 (FIG. 2). In other words, as shown in FIG. 2, each of pusher blades 28a, 28b, . . . 28n extends from the elastic band 26 at an identical angle with respect to the surface of the elastic band. Orientation of the pusher blades 28a, 28b, . . . 28n provides the angle of action, at which the tip of the blades contact the ring 50 such that the force F1 developed at the point of contact between each blade and the ring 50 in the direction of the blade oscillation has a component force F2 (FIG. 2) that pushes the ring 50, and hence, the rotor 40, in the direction of rotation shown in FIG. 2 by arrow R.

The band 26 is preferably made of an elastic material such as spring metal and is a unitary member to provide uniform distribution of the forces of interaction between the blades and the ring of the rotor.

The elastic band 26 has on one end inner torsion spirals 27a, 27b and has on the other end outer torsion spirals 27c, 27d, respectively. Once the elastic band 26 is wound around the periphery of the piezoelectric ring 46 with a tight fit, the torsion spirals on the mating ends of the band are mechanically engaged and securely retain the elastic band 26 about the piezoelectric ring 46 (see FIG. 2). The inner torsion spirals 27a and 27b at one end of the band curl upward, and the outer torsion spirals 27c and 27d curl downward (FIG. 3). The torsion spirals are preferably curled along the radius of an Archimedean spiral, although other curvilinear spiral configurations may be used. The torsion spirals 27a, 27b and 27c, 27d, when being mounted onto the piezoelectric ring 46, are positioned between two adjacent pusher blades to prevent interference between the pusher blades and the engaged torsion spirals. For assembling the elastic band 26 having the pusher blades 28a, 28b, . . . 28n with the piezoelectric ring 46, the elastic band 26 is wrapped around the piezoelectric ring 46 and is secured in tight engagement with its peripheral surface by securing the outer torsion spirals 27c and 27d over the inner tensional spirals 27a and 27b.

Initially, an elongated strip is stamped with a pattern that includes sections for pusher blades 28a, 28b, . . . 28n and torsion spirals 27a, 27b and 27c, 27d.

The coating on the pusher blades 28a, 28b, . . . 28n has a variable thickness so that the pusher blades 28a, 28b, . . . 28n are thicker at the base of the elastic band than at the tip of the blades. This is shown in FIG. 4 where the thickness “T” at the base of the blade, e.g., the blade 28a, is greater than the thickness “t” at the tip of the blade 28a.

The pusher blades 28a, 28b, . . . 28n can be coated with a polymeric material, preferably a polytetrafluoroethylene such as Teflon®, a trademark of DuPont. A thicker base of the blade eliminates weaknesses from the bend and improves resistance to wear. This coating is applied after the cutting and bending process. When the pusher blades 28a, 28b, . . . 28n are bent from the elongated strip, there is an increased thickening of material at the point of bending. The thickness of the coating from the base of the pusher blade to the tip of the pusher blade changes gradually. The functions of the coating are to restrict resonance of the blades and to dampen undesired vibrations.

FIG. 5 is a three-dimensional view of the collet 44, which is made from spring steel or other elastic material. The collet 44 consists of a flexible flange 44a and a splined cylindrical hub 44b with a plurality of slots 44-1, 44-2, . . . 44-m extending in the direction parallel to the shaft 38 (FIG. 1). The slots 44-1, 44-2, . . . 44-m terminate in circular holes 44-1a, 44-2a, . . . 44-ma formed in the flange 44a for improving flexibility of the collet 44.

The thickness of the walls of the collet hub 44b is about 1.2 mm, the width of the slots 44-1, 44-2, . . . 44-m (FIG. 4) is about 0.90 millimeter, and the diameter of the collet is about 25 mm. The slots are preferably formed by using an electro-erosion cutting process.

It has been shown that the piezoelectric ring 46 sits on the cylindrical hub 44b that can compensate radial inward/outward deformations of the piezoelectric ring 46 during its expansion/contraction movements. The cylindrical hub 44b supports the piezoelectric ring 46 with a tight fit. The piezoelectric ring 46 (FIG. 1), which is supported by the elastic collet 44, is preferably made of beryllium bronze.

In other words, the piezoelectric ring 46 is secured onto a stationary element by resilient contact over the outer surface of the elastic collet 44 with a predetermined secure retention. Resilient force of the collet 44 is transmitted outwardly, and the resilient contact area of the collet 44 is substantially equal to the area of the internal surface of the piezoelectric element 46.

The surface of the collet hub 44b may have a polymeric coating, e.g., of Teflon, and the coating (conventionally shown and designated by reference numeral 47 in FIG. 5) gradually decreases from the collet tip to the flange 44a. The coating 47 is initially applied over the external surface of the collet 44 using vacuum deposition. The thickness of the collet coating is in the general range of 0.3 to 0.4 mm.

To assemble the collet 44 that has the diameter of the collect hub 44b of about 25 mm, the hub is initially compressed to a diameter of 23.5 mm. The piezoelectric ring 46 is then placed onto the hub 44b, and the collet hub 44b is then released which elastically centers and secures the piezoelectric ring 46. The elastic band 26 and pusher blades 28a, 28b, . . . 28n are then squeezed onto the external surface of the piezoelectric ring 46 and retained by engaging the torsion spirals together. The elastic band 26 is preferably about 0.2 mm thick and has a manganese content of up to 2 percent and a silicone content of up to 1.5%. The band surface is coated with Teflon to a thickness of 0.1 to 0.15 millimeter.

The width of the elastic band 26 is essentially equal to or less than the width of the piezoelectric ring 46. The external diameter of the collet 44 is preferably greater than the internal diameter of the piezoelectric ring 46 by a magnitude at least equal to the magnitude of displacement at the oscillations of the piezoelectric ring 46. The width of the slots between the collet-supports is greater than the double displacement at the piezoelectric ring 46 oscillation. The collet 44 is longer than the width of the piezoelectric ring 46 by a magnitude equal to the side of the triangle of the ring-type thickening having a triangular section. The diameter of the ring that is formed when the elastic band 26 is deflected, without deformation of the torsion spirals, is less than the external diameter of the piezoelectric ring 46 by a magnitude, e.g., of the double displacement during oscillation. The piezoelectric ring 46 can be made as a ring with regular external and internal cylindrical surfaces, both having silver coatings 52a and 52b, respectively, as shown in FIG. 6, which is a cross-sectional view of the piezoelectric ring 46. The silver coatings 52a and 52b are used for soldering voltage-supply lead wires W1 and W2 from the power source (not shown).

In one practical embodiment, the diameter of the piezoelectric ring 46 was 24 mm and a width was of about 5.0 mm.

As mentioned above, the inner surface of the piezoelectric element 46 is mounted onto the support members of the collet 44, and the outer surface of the piezoelectric element engages the elastic band 26 (FIG. 2).

The rotor 40 is circumferentially disposed around the pusher blades 28a, 28b, . . . 28n such that the ends of the pusher blades contact the ring 50 on the inner circumference of the rotor 40 (FIGS. 1 and 2) and such that in operation, the piezoelectric ring 46 causes the pusher blades 28a, 28b, . . . 28n to apply a force on the ring 50 of the rotor 40, thereby causing rotation of the rotor 40 and the shaft 38 attached thereto.

When the piezoelectric element, i.e., the piezoelectric ring 46, is energized by applying voltage through the lead wires W1 and W2, the ring 46 begins to oscillate under inverse piezoelectric effect with a certain frequency in the range of 20 to 60 kHz, which is selected to be equal or substantially equal to the resonance frequency of longitudinal radial oscillations of the piezoelectric ring 46. In the embodiment of the invention shown in FIGS. 1 through 6, these oscillations occur with expansion/contraction of the piezoelectric ring 46 only in the radial direction and are compensated by flexibility of the collet 44.

Longitudinal, outward radial oscillations of the piezoelectric ring 46 with frequency ranging from 20 to 60 kHz will develop in each point of contact of the blade with the ring 50 a tangential component force F2 shown in FIG. 2 which will turn the rotor assembly 24 in the direction of arrow R.

In other words, when the piezoelectric ring 46 expands, its surface repositions the ring formed by the elastic band 26, in combination with the pusher blades 28a, 28b, . . . 28n, in the radial direction. The free tips of the pusher blades 28a, 28b, . . . 28n jam against the ring 50, creating a tangential component force F2 on the rotor 40, which causes the rotor 40 to turn through a certain angle.

When the piezoelectric ring 46 is compressed, the tips of the pusher blades 28a, 28b, . . . 28n move radially inward toward the center of the piezoelectric ring 46 under the action of elastic forces of the pusher blades 28a, 28b, . . . 28n and the collet 44 carrying the piezoelectric ring 46. The tips of the pusher blades 28a, 28b, . . . 28n break away from the surface of the ring 50 and occupy a new position in the peripheral direction of the rotor 40, slipping over the surface of the ring 50 toward the motion of the rotor 40. Repetition occurs in the event of oscillations of the piezoelectric element ring 46, causing a continuous rotary motion of the rotor 40. The angle of slippage of the pusher blades 28a, 28b, . . . 28n over the surface of the ring 50 increases due to the elastic flange 44a (FIGS. 1 and 4) of the collet 44. This increases efficiency of the transformation process, decreases specific consumption of the transformation of the reverse piezoelectric effect into rotation, and increases torque value.

FIGS. 7 and 8 illustrate another modification of the apparatus for transforming linear motion into rotary motion. FIG. 7 is a three-dimensional view of a collet 144, and FIG. 8 is a view similar to FIG. 2 that shows the structure that incorporates the collet 144. Since modification of FIGS. 7 and 8 is similar to the structure described above with reference to FIGS. 1 through 6, those parts and elements of the modified apparatus of FIGS. 7 and 8, which are identical to the previous embodiment, will be designated by the same reference numerals but with an addition of 100, and their descriptions will be omitted. For example, the apparatus of FIGS. 7 and 8 contains a stator assembly 122, a rotor assembly 124, a piezoelectric ring 146, etc.

The modification of FIGS. 7 and 8 differs from the previous embodiment by provision of a bracket-shaped insert 200 that has a radial portion 202 and two shoulders 204 and 206 on both ends of the radial portion. The shoulder 206 is wider that the slots. The radial portion 202 is inserted into a slot, e.g., 144-1 of the collet 144, so that the shoulder 206 abuts the inner surface of the hub 144b, while the shoulder 204 is placed onto the outer surface of the piezoelectric ring 146. It is understood that a plurality of such bracket-like elements is inserted between the collet 144 and the piezoelectric ring 146 for uniformity of action. Such a device makes it possible to more efficiently use the energy of the collet 144 when the latter is released from compression caused by contraction of the piezoelectric ring so that the energy accumulated in the compressed hub 144b is recoiled in the radial outward direction and is added to the radial outward movement imparted to the pusher blades 128a, 128b, . . . (FIG. 8) during their radial outward movement during expansion of the piezoelectric ring 146. In other words, the bracket-shaped insert 200 rigidly links the inner surface of the springing member with the outer surface of the ring-shaped piezoelectric element to use the energy of the springing member during expansion thereof after contraction by the inverse piezoelectric effect.

It is evident that many alternatives, modifications, and variations of the apparatus and method of the present invention will be apparent to those skilled in the art in light of the disclosure herein. It is intended that the metes and bounds of the present invention be determined by the appended claims rather than by the language of the above specification. It is also intended that all such alternatives, modifications, and variations which from a conjointly cooperative equivalent be included within the spirit and scope of these claims. For example, the rotor may be located inside the stator with the ring-shaped piezoelectric element surrounding the rotor and the pusher blades directed radially inward from the piezoelectric element. The piezoelectric ring can be made from a material different from that mentioned in the specification. The spiral springs may be curled with a profile different from the Archimedean spiral. The contact tips of the blades can be coated with a diamond coating or any other wear-resistant coating. The plastic coating on the blades can be different from Teflon.

1. An apparatus for transforming inverse piezoelectric effect into rotary motion comprising:
a stator assembly that comprises a stator, a ring-shaped piezoelectric element, and a source of alternating voltage connected to the ring-shaped piezoelectric element for causing repetitive expansions or contractions of the ring-shaped piezoelectric element under the inverse piezoelectric effect;
a rotor assembly having a rotor rotating installed in the stator assembly; and
a plurality of pusher blades between the rotor and the stator arranged at an angle to the stator such that the force that occurs at the point of contact of each blade with the stator has a component force that rotates the rotor in the circumferential direction;
said stator having a springing element that supports the ring-shaped piezoelectric element and compensates for the aforementioned repetitive expansions or contractions, the ring-shaped piezoelectric element having an inner surface and an outer surface.

2. The apparatus of claim 1 for transforming inverse piezoelectric effect into rotary motion, wherein the stator comprises a flange with a hub portion that contains a bearing unit, and wherein the rotor is made in the form of a cup-shaped body that surrounds the stator assembly and is supported by a shaft which is rotatingly supported by the aforementioned bearing unit, the aforementioned pusher blades extending radially outward from the outer surface of the ring-shaped piezoelectric element and uniformly spaced from each other in the circumferential direction on the ring-shaped piezoelectric element.

3. The apparatus of claim 1 for transforming inverse piezoelectric effect into rotary motion, wherein the springing element comprises a collet having an inner surface, an outer surface that tightly supports the inner surface of the ring-shaped piezoelectric element, and a plurality of slots arranged in the direction parallel to the aforementioned shaft.

4. The apparatus of claim 3 for transforming inverse piezoelectric effect into rotary motion, further comprising an elastic band that is wound onto the piezoelectric element, each of the aforementioned pusher blades being stamped out from the elastic band at an angle that provides generation of the aforementioned component force which rotates the rotor in the circumferential direction.

5. The apparatus of claim 4 for transforming inverse piezoelectric effect into rotary motion, where the elastic band is provided with tensional spirals that are formed on the ends of the elastic band for engagement with each other when the elastic band is wound onto the piezoelectric element and for creating the aforementioned tension.

6. The apparatus of claim 2 for transforming inverse piezoelectric effect into rotary motion, wherein the springing element comprises a collet having an inner surface, an outer surface that tightly supports the inner surface of the ring-shaped piezoelectric element, and a plurality of slots arranged in the direction parallel to the aforementioned shaft.

7. The apparatus of claim 6 for transforming inverse piezoelectric effect into rotary motion, further comprising an elastic band that is wound onto the piezoelectric element, each of the aforementioned pusher blades being stamped out from the elastic band at an angle that provides generation of the aforementioned component force which rotates the rotor in the circumferential direction.

8. The apparatus of claim 7 for transforming inverse piezoelectric effect into rotary motion, where the elastic band is provided with tensional spirals that are formed on the ends of the elastic band for engagement with each other when the elastic band is wound onto the piezoelectric element and for creating the aforementioned tension.

9. The apparatus of claim 4 for transforming inverse piezoelectric effect into rotary motion, wherein each pusher blade has a base at the point of connection with the elastic band and a tip at the point of contact with the stator, each pusher blade being thicker at the base and thinner at the tips.

10. The apparatus of claim 5 for transforming inverse piezoelectric effect into rotary motion, wherein each pusher blade has a base at the point of connection with the elastic band and a tip at the point of contact with the stator, each pusher blade being thicker at the base and thinner at the tips.

11. The apparatus of claim 2 for transforming inverse piezoelectric effect into rotary motion, where the rotor has an inner surface and a rotor ring of a wear-resistant material with a high coefficient of friction that covers the aforementioned inner surface of the rotor and is in contact with the pusher blades.

12. The apparatus of claim 3 for transforming inverse piezoelectric effect into rotary motion, where the rotor has an inner surface and a rotor ring of a wear-resistant material with a high coefficient of friction that covers the aforementioned inner surface of the rotor and is in contact with the pusher blades.

13. The apparatus of claim 6 for transforming inverse piezoelectric effect into rotary motion, where the rotor has an inner surface and a rotor ring of a wear-resistant material with a high coefficient of friction that covers the aforementioned inner surface of the rotor and is in contact with the pusher blades.

14. The apparatus of claim 3 for transforming inverse piezoelectric effect into rotary motion, further provided with at least one bracket-like element that rigidly links the outer surface of the ring-shaped piezoelectric element with the inner surface of the collet so that when the collet is expanded after contraction by the inverse piezoelectric effect, the collet adds its expansion energy to the expansion of the ring-shaped piezoelectric element.

15. The apparatus of claim 12 for transforming inverse piezoelectric effect into rotary motion, further provided with at least one bracket-like element that rigidly links the outer surface of the ring-shaped piezoelectric element with the inner surface of the collet so that when the collet is expanded after contraction by the inverse piezoelectric effect, the collet adds its expansion energy to the expansion of the ring-shaped piezoelectric element.

16. A method of manufacturing the apparatus for transforming inverse piezoelectric effect into rotary motion, the method comprising the steps of:
providing a ring-shaped piezoelectric element having inner and outer surfaces and capable of contracting and expanding under the inverse piezoelectric effect;
providing a springing member that can be contracted and expanded in the radial direction of the ring-shaped piezoelectric element;
placing the ring-shaped piezoelectric element onto the springing member for compensating radial contractions and expansions of the ring-shaped piezoelectric element;
providing an elastic band of a springing material;
stamping out pusher blades at a predetermined angle from the elastic band and simultaneously stamping out engagement elements on both ends of the elastic band;
winding the elastic band onto the ring-shaped piezoelectric element and engaging the engagement elements so that the elastic band is tightly fit on the ring-shaped piezoelectric element;
providing a stator that supports a bearing unit;
providing a rotor that has an inner surface; and
supporting the rotor rotatingly onto the aforementioned bearing unit and around the ring-shaped piezoelectric element so that the pusher blades assume a position relative to the rotor at an angle such that when the pusher blades perform radial outward movements under the inverse piezoelectric effect, the force in contact between the pusher blades and the aforementioned inner surface of the rotor has a component that rotates the rotor.

17. The method of claim 16, further providing the step of coating the pusher blades with a material that restricts resonance of the blades and dampens undesired vibrations.

18. The method of claim 16, wherein the springing member has an inner surface and the ring-shaped piezoelectric element has an outer surface, the method further comprising the step of rigidly linking the inner surface of the springing member with the outer surface of the ring-shaped piezoelectric element for using the energy of the springing member during expansion thereof after contraction by the inverse piezoelectric effect.
